(19) United States
(12) Patent Application Publication
(10) Pub. No.: US 2019/0088449 A1
(43) Pub. Date: Mar. 21, 2019

(54) SUBSTRATE TREATING APPARATUS AND SUBSTRATE TREATING METHOD

(71) Applicant: Semes Co., Ltd., Chungcheongnam-do (KR)

(72) Inventors: Ogsen Galstyan, Chungcheongnam-do (KR); Harutyun Melikyan, Cheonan-si (KR); Young Bin Kim, Gyeonggi-do (KR); Jong Hwan An, Gyeonggi-do (KR)

(21) Appl. No.: 16/120,498

(22) Filed: Sep. 4, 2018

(30) Foreign Application Priority Data
Sep. 21, 2017 (KR) 10-2017-0121706
Nov. 20, 2017 (KR) 10-2017-0154769

(51) Int. Cl. H01J 37/32; H01L 21/683

(52) U.S. Cl. CPC H01J 37/3211; H01L 21/6833; H01J 37/32458; H01J 37/32642; H01J 37/32449; H01J 37/32724; H01J 37/32633; H01J 37/32834; H01J 37/32568

(57) ABSTRACT

Disclosed is a substrate treating apparatus. The substrate treating apparatus includes a process chamber having a treatment space in the interior thereof, a support unit configured to support a substrate in the treatment space, a gas supply unit configured to supply a treatment gas into the treatment space, and a plasma generating unit configured to generate plasma from the gas in the treatment space, wherein the plasma generating unit includes a high-frequency power source, a high-frequency antenna, to which a current is applied from the high-frequency power source, and an additional antenna provided to be spaced apart from the high-frequency antenna and to which a coupling current is applied from the high-frequency antenna.

### CROSS-REFERENCE TO RELATED APPLICATIONS

This application claims priority under 35 U.S.C. § 119 to Korean Patent Application No. 10-2017-0121706 filed on Sep. 21, 2017 and Korean Patent Application No. 10-2017-0154769 filed on Nov. 20, 2017, in the Korean Intellectual Property Office, the disclosures of which are incorporated by reference herein in their entireties.

### BACKGROUND

Embodiments of the inventive concept described herein relate to a substrate treating apparatus and a substrate treating method, and more particularly to a substrate treating apparatus that may uniformly supply plasma to all areas on a substrate, and a substrate treating method thereof.

A semiconductor manufacturing process may include a process of treating a substrate by using plasma. For example, in an etching process of the semiconductor process, a thin film on the substrate may be removed by using plasma.

In order to use plasma in a substrate treating process, a plasma generating unit that may generate plasma is mounted in a process chamber. The plasma generating units are classified into a capacitively coupled plasma type and an inductively coupled plasma type according to plasma generating schemes. A CCP type source is disposed in a chamber such that two electrodes face each other, and an RF signal is applied to any one or both of the two electrodes to generate an electric field in the chamber so as to generate plasma. Meanwhile, in an ICP type source, one or more coils are installed in a chamber, and plasma is generated by inducing an electric field in the chamber by applying an RF signal to the coils.

Referring to FIG. 1, in the conventional ICP type, currents supplied to antennas and phases of the currents are controlled such that the density of plasma supplied onto a substrate are controlled, and the density of the plasma supplied to an edge area of the substrate cannot be adjusted.

### SUMMARY

Embodiments of the inventive concept provide a substrate treating apparatus that may adjust the density of plasma supplied to an edge area of a substrate, and a substrate treating method thereof.

The problems that are to be solved by the inventive concept are not limited to the above-mentioned problems, and the unmentioned problems will be clearly understood by those skilled in the art to which the inventive concept pertains from the specification and the accompanying drawings.

In accordance with an aspect of the inventive concept, there is provided a substrate treating apparatus including a process chamber having a treatment space in the interior thereof, a support unit configured to support a substrate in the treatment space, a gas supply unit configured to supply a treatment gas into the treatment space, and a plasma generating unit configured to generate plasma from the gas in the treatment space, wherein the plasma generating unit includes a high-frequency power source, a high-frequency antenna, to which a current is applied from the high-frequency power source, and an additional antenna provided to be spaced apart from the high-frequency antenna and to which a coupling current is applied from the high-frequency antenna.

The additional antenna may be provided independently from the high-frequency power source.

The additional antenna may be a closed circuit.

The additional antenna may be provided such that an area provided with the additional antenna overlaps a peripheral area of the interior of the treatment space when viewed from the top.

The additional antenna may include a plurality of additional coils, and wherein the plurality of additional coils is disposed along a lengthwise direction of the high-frequency antenna.

Additional capacitors may be connected to the additional coils.

Some of the additional capacitors connected to the additional coils may have different capacitance.

The additional capacitors may be variable capacitors.

The plurality of additional coils may be provided outside the high-frequency antenna.

The high-frequency antenna may include an external antenna, the external antenna may include a plurality of external coils, and one of the additional coils may be coupled to one of the external coils and the additional coils are coupled to different external coils.

The high-frequency antenna may further include an internal antenna disposed inside the external antenna.

The plasma generating unit may further include a controller configured to control the densities of plasma of areas that are opposite to the plurality of additional coils by individually adjusting the capacitance of the additional capacitors.

The support unit may further include a sensor configured to detect the densities of plasma for areas of the substrate, and the controller may adjust the capacitors of the additional capacitors based on the densities of plasma for the areas, which has been detected by the sensor.

In accordance with another aspect of the inventive concept, there is provided a plasma generating apparatus including a high-frequency power source, a high-frequency antenna, to which a current is applied from the high-frequency power source, and an additional antenna provided to be spaced apart from the high-frequency antenna and coupled to the high-frequency antenna such that a coupling current is applied from the high-frequency antenna to the additional antenna.

The high-frequency antenna may further include an external antenna, the external antenna may include an external coil, one end of which is connected to the high-frequency antenna and an opposite end of which is grounded, the additional antenna may include a plurality of additional coils that are provided independently from the high-frequency power source, and the additional coils may be coupled to the external coil.

Additional capacitors may be connected to the additional coils.

Some of the additional capacitors connected to the additional coils may have different capacitance.

The additional capacitors may be variable capacitors.

The plasma generating apparatus may further include a controller configured to control the densities of plasma of areas that are opposite to the plurality of additional coils by individually adjusting the capacitance of the additional capacitors.

In accordance with another aspect of the inventive concept, there is provided a substrate treating method of a substrate treating apparatus, the substrate treating apparatus including a process chamber having a treatment space in the interior thereof, a high-frequency antenna configured to generate plasma in the treatment space, and an additional antenna, to which a coupling current is applied from the high-frequency antenna, the method including controlling the density of plasma of a peripheral area of the interior of the treatment space by controlling the additional antenna.

The additional antenna may include a plurality additional coils, and additional capacitors connected to the additional coils.

Some of the additional capacitors may have different capacitance.

The additional capacitors may be variable capacitors, and the controlling of the plasma may include controlling the densities of the plasma of areas that are opposite to the plurality of additional coils by individually adjusting the capacitance of the additional capacitors.

The substrate treating method may further include detecting the densities of plasma for areas of the substrate, and the controlling of the plasma may include adjusting the capacitance of the additional capacitors based on the densities of plasma for areas of the substrate.

### BRIEF DESCRIPTION OF THE FIGURES

The above and other objects and features of the inventive concept will become apparent by describing in detail exemplary embodiments thereof with reference to the accompanying drawings.

FIG. 1 is a view illustrating that the density of plasma supplied onto a substrate is not uniformly supplied onto a substrate in a conventional; substrate treating apparatus;

FIG. 2 is a view illustrating a substrate treating apparatus according to an embodiment of the inventive concept;

FIG. 3 is a view illustrating a plasma generating unit according to an embodiment of the inventive concept;

FIG. 4 is a view illustrating a process of controlling the densities of plasma for areas of a substrate by a plasma generating unit according to an embodiment of the inventive concept;

FIG. 5 is a circuit diagram illustrating a plasma generating unit according to an embodiment of the inventive concept;

FIGS. 6 to 8 are circuit diagrams illustrating plasma generating units according to various embodiments of the inventive concept; and

FIG. 9 is a flowchart illustrating a substrate treating method according to an embodiment of the inventive concept.

FIGS. 10 and 11 are exemplary views of a substrate treating apparatus according to another embodiment of the inventive concept.

### DETAILED DESCRIPTION

The embodiments of the inventive concept may be modified in various forms, and the scope of the inventive concept should not be construed to be limited by the embodiments of the inventive concept described in the following. The embodiments of the inventive concept are provided to describe the inventive concept for those skilled in the art more completely. Accordingly, the shapes and the like of the components in the drawings are exaggerated to emphasize clearer descriptions.

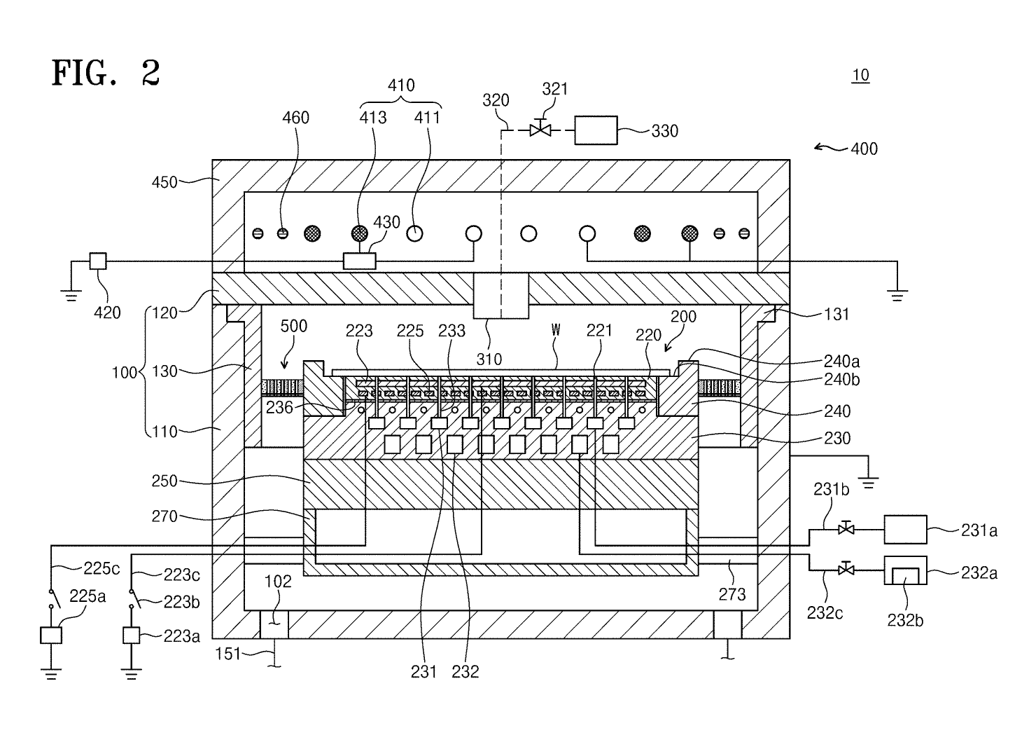

FIG. 2 is a view exemplarily illustrating a substrate treating apparatus 10 according to an embodiment of the inventive concept.

Referring to FIG. 2, the substrate treating apparatus 10 treats a substrate W by using plasma. For example, the substrate treating apparatus 10 may perform an etching process on the substrate W. The substrate treating apparatus 10 may include a process chamber 100, a support unit 200, a gas supply unit 300, a plasma generating unit 400, and a baffle unit 500.

The process chamber 100 provides a space in which a substrate treating process is executed. The process chamber 100 includes a housing 110, a closing cover 120, and a liner 130.

The housing 110 has an open-topped space in the interior thereof. The interior space of the housing 110 is provided as a treatment space in which a substrate treating process is performed. The housing 110 is formed of a metallic material. The housing 110 may be formed of aluminum. The housing 110 may be grounded. An exhaust hole 102 is formed on a bottom surface of the housing 110. The exhaust hole 102 is connected to an exhaust line 151. The reaction side-products generated in the process and gases left in the interior space of the housing may be discharged to the outside through the exhaust line 151. Through the exhaustion process, the pressure of the interior of the housing 110 is reduced to a specific pressure.

The closing cover 120 covers an opened upper surface of the housing 110. The closing cover 120 has a plate shape, and the interior space of the housing 110 is closed. The closing cover 120 may include a dielectric window.

The liner 130 is provided in the interior of the housing 110. The liner 130 is formed in the interior of an interior space, an upper surface and a lower surface of which are opened. The liner 130 may have a cylindrical shape. The liner 130 may have a radius corresponding to an inner surface of the housing 110. The liner 130 is provided along the inner surface of the housing 110. A support ring 131 is formed at an upper end of the liner 130. The support ring 131 is a ring-shaped plate, and protrude to the outside of the liner 130 along the circumference of the liner 130. The support ring 131 is positioned at an upper end of the housing 110, and supports the liner 130. The liner 130 may be formed of the same material as the housing 110. That is, the liner 130 may be formed of aluminum. The liner 130 protects the inner surface of the housing 110. In a process of exciting a process gas, arc discharging is generated in the interior of the chamber 100. The arc discharging damages peripheral devices. The liner 130 may prevent an inner surface of the housing 110 from being damaged due to arc discharging by protecting the inner surface of the housing 110. Further, the side-products generated in the substrate treating process are prevented from being deposited on the inner wall of the housing 110. The liner 130 is inexpensive and may be easily exchanged as compared with the housing 110. Accordingly, when the liner 130 is damaged due to arc discharging, the operation may exchange the liner 130 with a new liner 130.

The substrate support unit 200 is situated in the interior of the housing 110. The substrate supporting unit 200 supports the substrate W. The substrate support unit 200 may include an electrostatic chuck 210 configured to suction the substrate W by using an electrostatic force. Unlike this, the substrate support unit 200 may support the substrate W in various methods such as mechanical clamping. Hereinafter, the substrate support unit 200 including the electrostatic chuck 210 will be described.

The support unit 200 includes an electrostatic chuck 210, an insulation plate 250, and a lower cover 270. The support unit 200 may be located in the interior of the chamber 100 to be spaced upwards apart from the bottom surface of the housing 110.

The electrostatic chuck 210 includes a dielectric plate 220, an electrode 223, a heater 225, a support plate 230, and a focusing ring 240.

The dielectric plate 220 is located at an upper end of the electrostatic chuck 210. The dielectric plate 220 may be formed of a dielectric substance of a disk shape. The substrate W is positioned on the upper surface of the dielectric plate 220. The upper surface of the dielectric plate 220 has a diameter that is smaller than that of the substrate W. Accordingly, a peripheral area of the substrate W is located on an outer side of the dielectric plate 220. A first supply passage 221 is formed in the dielectric plate 220. The first supply passage 221 extends from an upper surface to a bottom surface of the dielectric plate 210. A plurality of first supply passages 221 are formed to be spaced apart from each other to be provided as passages through which a heat transfer medium is supplied to the bottom surface of the substrate W.

A lower electrode 223 and a heater 225 are buried in the dielectric plate 220. The lower electrode 223 is located above the heater 225. The lower electrode 223 is electrically connected to a first lower power source 223a. The first lower power source 223a includes a DC power source. A switch 223b may be installed between the lower electrode 223 and the first lower power source 223a. The lower electrode 223 may be electrically connected to the first lower power source 223a through switching-on/off of the switch 223b. If the switch 223b is turned on, a DC current is applied to the lower electrode 223. An electrostatic force may be applied between the lower electrode 223 and the substrate W by a current applied to the lower electrode 223, and the substrate W may be suctioned to the dielectric plate 220 by the electrostatic force.

The heater 225 is electrically connected to a second lower power source 225a. The heater 225 generates heat by a resistance due to a current applied to the second power source 225a. The generated heat is transferred to the substrate W through the dielectric plate 220. The substrate W is maintained at a specific temperature by the heat generated by the heater 225. The heater 225 includes a spiral coil.

The support plate 230 is located below the dielectric plate 220. A bottom surface of the dielectric plate 220 and an upper surface of the support plate 230 may be bonded to each other by an adhesive 236. The support plate 230 may be formed of aluminum. An upper surface of the support plate 230 may be stepped such that a central area thereof is higher than a peripheral area thereof. The central area of the upper surface of the support plate 230 has an area corresponding to a bottom surface of the dielectric plate 220, and is bonded to the bottom surface of the dielectric plate 220. The support plate 230 has a first circulation passage 231, a second circulation passage 232, and a second supply passage 233.

The first circulation passage 231 is provided as a passage, through which the heat transfer medium circulates. The first circulation passage 231 may be formed in the interior of the support plate 230 to have a spiral shape. Further, the first circulation passage 231 may be disposed such that passages having ring shapes of different radii have the same center. The first circulation passages 231 may communicate with each other. The first circulation passages 231 are formed at the same height.

The second circulation passage 232 is provided as a passage, through which a cooling fluid circulates. The second circulation passage 232 may be formed in the interior of the support plate 230 to have a spiral shape. Further, the second circulation passages 232 may be disposed such that passages having ring shapes of different radii have the same center. The second circulation passages 232 may communicate with each other. The second circulation passages 232 may have a sectional area that is larger than that of the first circulation passage 231. The second circulation passages 232 are formed at the same height. The second circulation passages 232 may be located under the first circulation passages 231.

The second supply passages 233 extend upwards from the first circulation passages 231, and are provided on an upper surface of the support plate 230. The number of the second supply passages 243 corresponds to the first supply passages 221 and the second supply passages 243 connect the first circulation passages 231 and the first supply passages 221.

The first circulation passages 231 are connected to a heat transfer medium storage 231a through heat transfer medium supply lines 231b. A heat transfer medium is stored in the heat transfer medium storage 231a. The heat transfer medium includes an inert gas. According to an embodiment, the heat transfer medium includes a helium (He) gas. The helium gas may be supplied to the first circulation passages 231 through supply lines 231b, and may be supplied to the bottom surface of the substrate W after sequentially passing through the second supply passages 233 and the first supply passages 221. The helium gas functions as a medium by which the heat transferred from plasma to the substrate W is transferred to the electrostatic chuck 210.

The second circulation passages 232 are connected to the cooling fluid storage 232a through the cooling fluid supply lines 232c. The cooling fluid storage 232a may store a cooling fluid. A cooler 232b may be provided in the cooling fluid storage 232a. The cooler 232b cools the cooling fluid to a specific temperature. Unlike this, the cooler 232b may be installed on the cooling fluid supply line 232c. The cooling fluid supplied to the second circulation passages 232 through the cooling fluid supply lines 232c cools the support plate 230 while circulating along the second circulation passages 232. The support plate 230 may cool the dielectric plate 220 and the substrate W together while being cooled to maintain the substrate W at a specific temperature.

The focus ring 240 is disposed at a peripheral area of the electrostatic chuck 210. The focus ring 240 has a ring shape and may be disposed along a circumference of the dielectric plate 220. An upper surface of the focus ring 240 may be stepped such that an outer side 240a thereof is higher than an inner side 240b thereof. The inner side 240b of the upper surface of the focus ring 240 is located at the same height as that of the upper surface of the dielectric plate 220. The inner side 240b of the upper surface of the focus ring 240 supports a peripheral area of the substrate W located on an outside of the dielectric plate 220. The outside 240a of the focus ring 240 is provided to surround a peripheral area of the substrate W. The focus ring 240 allows plasma to be concentrated in an area that faces the substrate W in the chamber 100.

The insulation plate 250 is located below the support plate 230. The insulation plate 250 has a cross-sectional area corresponding to that of the support plate 230. The insulation plate 250 is located between the support plate 230 and the lower cover 270. The insulation plate 250 is formed of an insulating material, and electrically insulates the support plate 230 and the lower cover 270.

The lower cover 270 is located at a lower end of the substrate support unit 200. The lower cover 270 is spaced upwards apart from the bottom surface of the housing 110. An open-topped space is formed in the interior of the lower cover 270. The upper surface of the lower cover 270 is covered by the insulation plate 250. Accordingly, the outer radius of the section of the lower cover 270 is the same as the outer radius of the insulation plate 250. A lift pin module (not illustrated) that moves the transferred substrate W from a transfer member on the outside to the electrostatic chuck 210 may be located in the interior space of the lower cover 270.

The lower cover 270 has a connecting member 273. The connecting member 273 connects an outer surface of the lower cover 270 and an inner wall of the housing 110. A plurality of connecting members 273 may be provided on an outer surface of the lower cover 270 at a specific interval. The connecting members 273 support the substrate support unit 200 in the interior of the chamber 100. Further, the connecting members 273 are connected to an inner wall of the housing 110 such that the lower cover 270 is electrically grounded. A first power line 223c connected to the first lower power source 223a, a second power line 225c connected to the second lower power source 225a, a heat transfer medium supply line 231b connected to the heat transfer medium storage 231a, and a cooling fluid supply line 232c connected to the cooling fluid storage 232a may extend into the lower cover 270 through the interior space of the connecting member 273.

The gas supply unit 300 supplies a process gas into the chamber 100. The gas supply unit 300 includes a gas supply nozzle 310, a gas supply line 320, and a gas storage unit 330. The gas supply nozzle 310 is installed at a central portion of the closing cover 120. An ejection hole is formed on the bottom surface of the gas supply nozzle 310. The ejection hole is located below the closing cover 120, and supplies the process gas into the treatment space in the interior of the chamber 100. The gas supply unit 320 connects the gas supply nozzle 310 and the gas storage unit 330. The gas supply line 320 supplies the process gas stored in the gas storage unit 330 to the gas supply nozzle 310. A valve 321 is installed in the gas supply line 320. The valve 321 opens and closes the gas supply line 320, and adjusts a flow rate of the process gas supplied through the gas supply line 320.

The plasma generating unit 400 excites a process gas in the chamber 100 into a plasma state. According to an embodiment of the inventive concept, the plasma generating unit 400 is of an ICP type.

The plasma generating unit 400 includes a high-frequency antenna 410, a high-frequency power source 420, and an additional antenna 460.

The high-frequency antenna 410 receives a current from the high-frequency power source 420 and generates plasma by using an electric field. Although FIG. 2 illustrates that the high-frequency antenna 410 includes an internal antenna 411 and an external antenna 413, the inventive concept is not limited thereto but one or three antennas may be provided. The high-frequency power source 420 supplies a high-frequency signal. As an example, the high-frequency power source 420 may be an RF power source that supplies RF power.

The additional antenna 460 may be spaced apart from the high-frequency antenna 410, and may receive a coupling current from the high-frequency antenna 410. Although FIG. 2 illustrates that the additional antenna 460 is provided outside the high-frequency antenna 410, the additional antenna 460 also may be provided inside the high-frequency antenna 410. The additional antenna 460 is not connected to the high-frequency power source 420, and is provided independently from the high-frequency power source 420. Further, the additional antenna 460 may be a closed circuit.

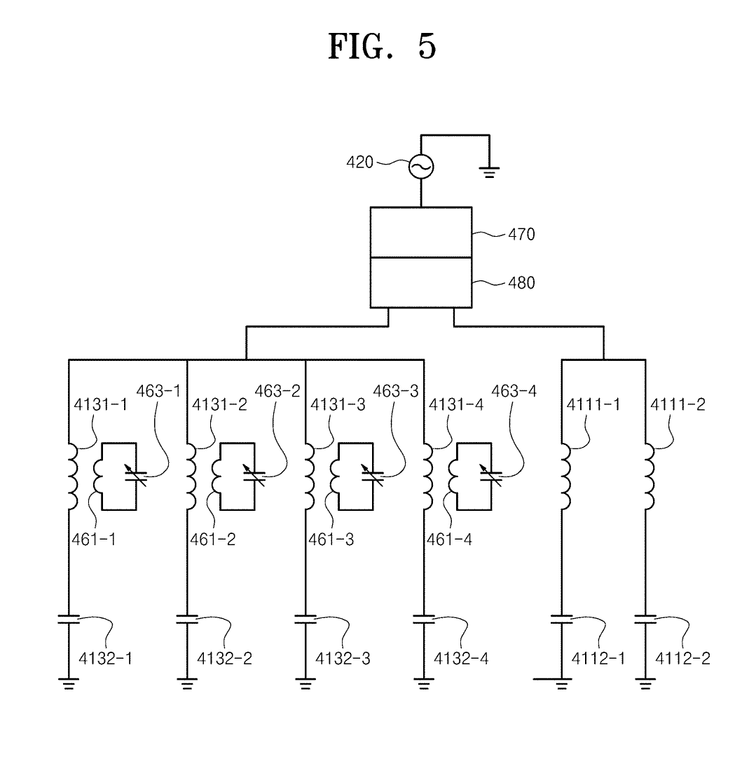

Further, the additional antenna 460 may be provided such that an area provided with the additional antenna 460 overlaps a peripheral area of the interior of the treatment space of the process chamber 100 when viewed from the top. That is, the additional antenna 460 may be provided at a location corresponding to an edge area of the substrate to control the density of the plasma supplied to an edge area of the substrate. A detailed configuration of the additional antenna 460 will be described below with reference to FIGS. 5 to 7.

The baffle unit 500 is located between an inner wall of the housing 110 and the substrate support unit 200. The baffle unit 500 includes a baffle having through-holes. The baffle has an annular ring shape. A process gas provided into the housing 110 is exhausted through the exhaust hole 102 after passing through the through-holes of the baffle. The flow of the process gas may be controlled according to the shape of the baffle and the shapes of the through-holes.

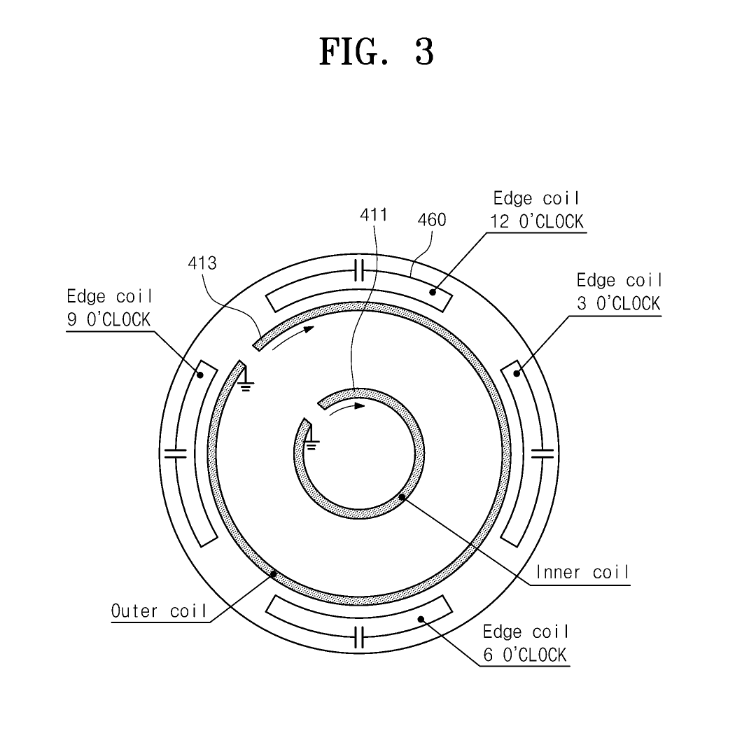

FIG. 3 is a view illustrating a plasma generating unit according to an embodiment of the inventive concept.

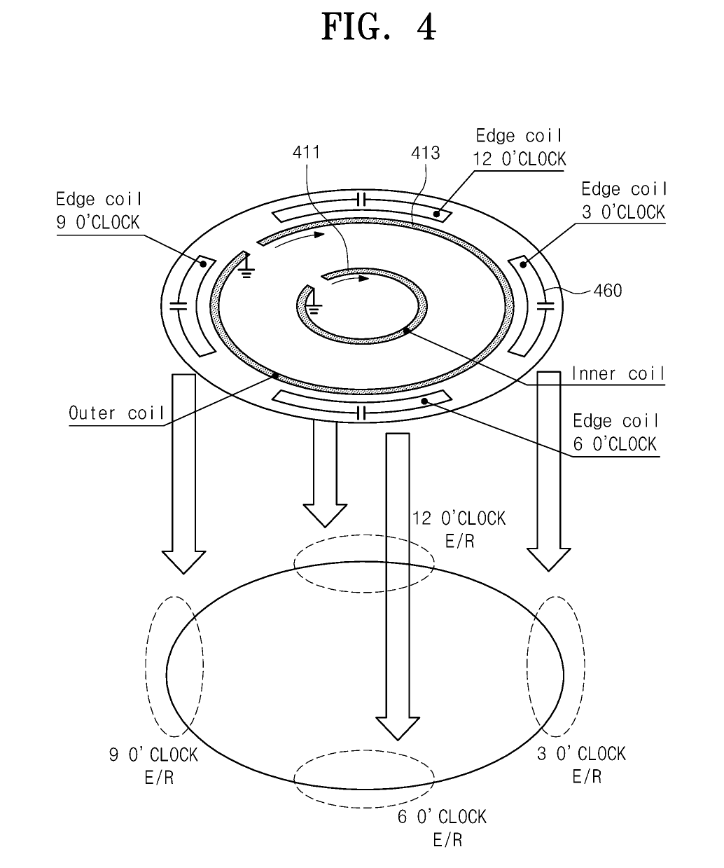

As an example, the plasma generating unit 400 may include an internal antenna 411, an external antenna 413, and an additional antenna 460. A current is applied to the internal antenna 411 and the external antenna 414 from an external high-frequency power source, and the densities of plasma for areas of the substrate are uniformly controlled by controlling the current supplied to the internal antenna 411 and the external antenna 413. When plasma is generated only by the internal antenna 411 and the external antenna 413, a small amount of plasma is supplied to the edge area of the substrate and plasma is not uniformly formed in the whole substrate, but according to the plasma generating unit 400 of the inventive concept, because the additional antenna 460 is provided on the outside of the external antenna 413, plasma may be uniformly supplied even to the edge area of the substrate by the plasma generated by the additional antenna 460. In this case, the additional antenna 460 is not connected to a high-frequency power source, and may receive a coupling current from the external antenna 413 to generate plasma. Further, the external antenna 413 includes a capacitor, and may control the amount of the plasma supplied to the edge area of the substrate by adjusting an impedance value with the capacitor. Accordingly, as illustrated in FIG. 4, plasma may be uniformly supplied to all areas of the substrate. As an example, as illustrated in FIG. 4, when the additional antenna 460 includes four additional coils, plasma supplied to the edge areas of a 12 O'clock direction, a 3 O'clock direction, a 6 O'clock direction, and a 9 O'clock direction of the substrate may be adjusted by using the additional coils and the additional capacitors provided to the 12 O'clock direction, the 3 O'clock direction, the 6 O'clock direction, and the 9 O'clock direction.

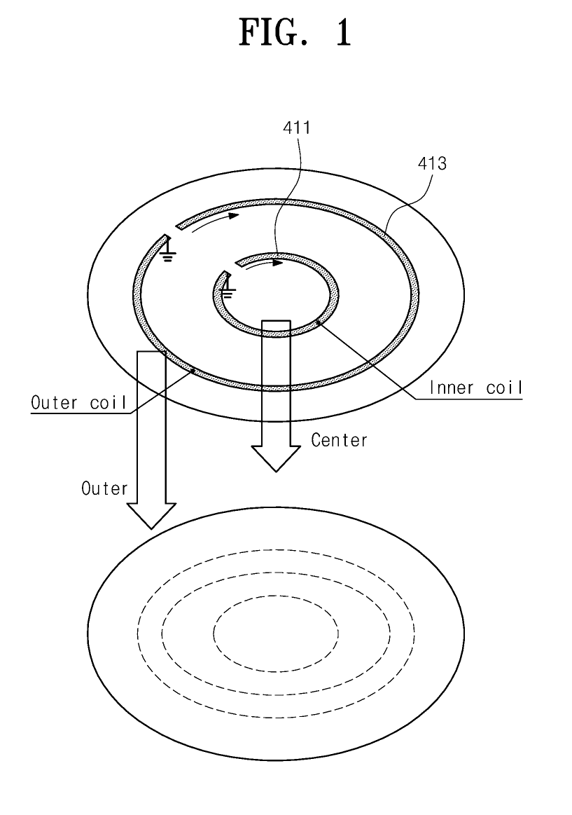

Further, differently from the high-frequency antenna 410 of FIG. 3, the additional antenna of the inventive concept may be provided for the antenna illustrated in FIGS. 1 to 4 of Korean Patent No. 10-1125624. That is, the additional antenna according to the inventive concept is provided on the outside of the antenna illustrated in Korean Patent No. 10-1125624 so that the density of plasma supplied to the edge area of the substrate may be controlled. That is, the additional antenna according to the inventive concept may be provided to be spaced apart from various forms of high-frequency antennas that are connected to a high-frequency power source, and accordingly may uniformly control the density of plasma that is supplied onto the substrate.

FIG. 5 is a circuit diagram illustrating a plasma generating unit according to an embodiment of the inventive concept.

Referring to FIG. 5, the plasma generating unit 400 according to an embodiment of the inventive concept includes a high-frequency power source 420, an internal antenna 411, an external antenna 413, an additional antenna 460, an impedance matching device 470, and a splitter 480.

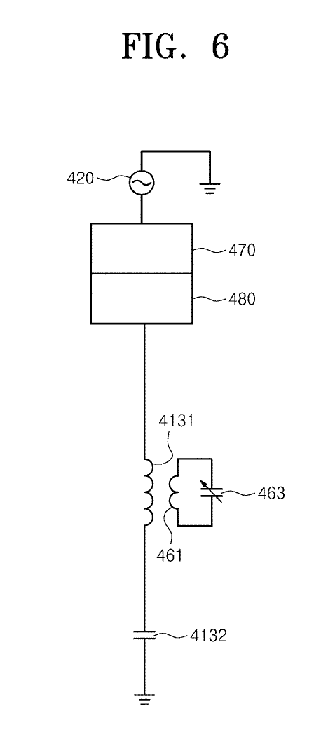

The external antenna 413 may include a plurality of external coils 4131-1, 4131-2, 4131-3, and 4131-4 and a plurality of external capacitors 4132-1, 4132-2, 4132-3, and 4132-4, and the additional antenna 460 may include a plurality of additional coils 461-1, 461-2, 461-3, and 461-4 and a plurality of capacitors 463-1, 463-2, 463-3, and 463-4. The plurality of additional coils 461-1, 461-2, 461-3, and 461-4 may be disposed along a lengthwise direction of the external antenna 413. Further, one of the plurality of additional coils 461-1, 461-2, 461-3, and 461-4 may be coupled to one of the plurality of external coils 4131-1, 4131-2, 4131-3, and 4131-4. That is, the first additional coil 461-1 may be coupled to the first external coil 4131-1, the second additional coil 461-2 may be coupled to the second external coil 4131-2, the third additional coil 461-3 may be coupled to the third external coil 4131-3, and the fourth additional coil 461-4 may be coupled to the fourth external coil 4131-4. Accordingly, the additional antenna 460 may be supplied with coupling power by the external antenna 413 even though it is not connected to the high-frequency power source 420. However, although FIG. 5 illustrates that four external antennas and four additional antennas 460 are provided, the inventive concept is not limited thereto but as illustrated in FIG. 6, one high-frequency antenna 410 and one additional antenna 460 may be provided and two or four high-frequency antennas 410 and additional antennas 460 may be provided.

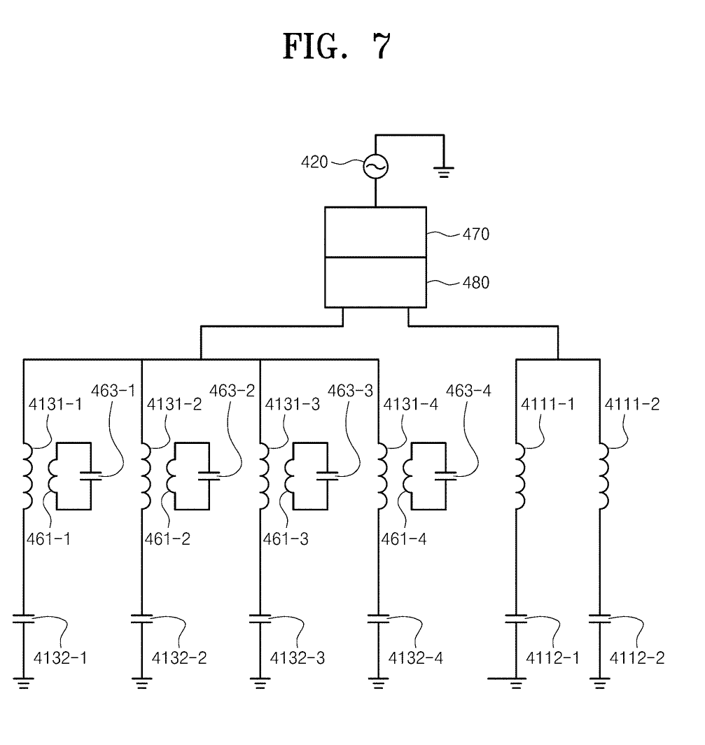

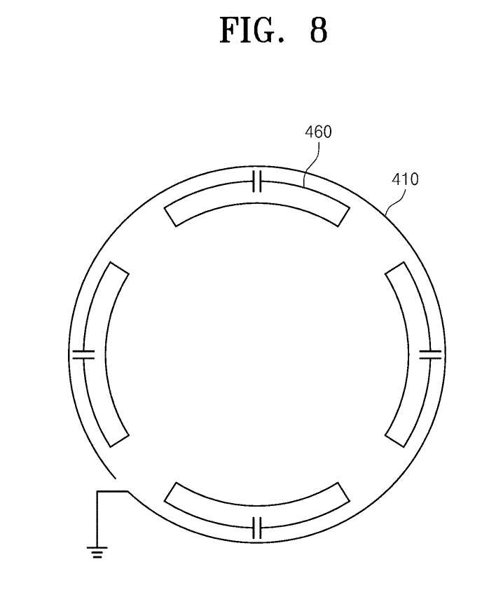

Further, the plurality of additional coils 461-1, 461-2, 461-3, and 461-4 may be connected to the plurality of additional capacitors 463-1, 463-2, 463-3, and 463-4, and the plurality of additional capacitors 463-1, 463-2, 463-3, and 463-4 may be variable capacitors. In this case, the controller (not illustrated) may control the densities of plasma of areas that are opposite to the plurality of additional coils 461-1, 461-2, 461-3, and 461-4 by individually adjusting the capacitance of the plurality of additional capacitors 463-1, 463-2, 463-3, and 463-4. Further, the controller (not illustrated) may adjust the capacitance of the plurality of additional capacitors 463-1, 463-2, 463-3, and 463-4 based on the densities of plasma for areas of the substrate, which is detected by a sensor included in the support unit 200. That is, the controller (not illustrated) may adjust the capacitance of the additional capacitors 463 such that a current that is supplied to an additional coil 461 that is opposite to an area of the substrate, which has a high density of plasma, or may adjust the capacitance of the additional capacitors 463 such that a current that is supplied to an additional coil 461 that is opposite to an area of the substrate, which is a low density of plasma. Accordingly, because the density of plasma of an edge area of the substrate may be controlled, the plasma may be uniformly supplied to all areas of the substrate. However, the additional capacitors 463-1, 463-2, 463-3, and 463-4 are not limited to variable capacitors, and as illustrated in FIG. 7, may be fixed capacitors. In this case, some of the additional capacitors 463-1, 463-2, 463-3, and 463-4 may have different capacitance, and the densities of plasma of the areas that are opposite to the plurality of additional coils 461-1, 461-2, 461-3, and 461-4. The impedance matching device 470 may be located between the high-frequency power source 420 and the high-frequency antenna 410 to perform impedance matching, and the splitter 480 may distribute a current supplied from the high-frequency power source 420. Further, although it has been described in the embodiment that the additional antenna 460 is disposed outside the high-frequency antenna 410, the additional antenna 460 may be disposed inside the high-frequency antenna 410 as illustrated in FIG. 8.

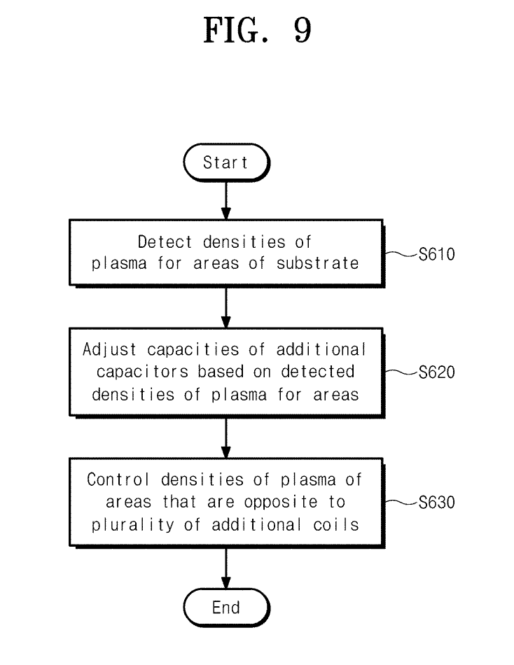

FIG. 9 is a flowchart illustrating a substrate treating method according to an embodiment of the inventive concept.

Referring to FIG. 9, first, the densities of plasma for areas of the substrate are detected (S610). In this case, the densities of the plasma for the areas of the substrate may be detected by a sensor located in the support unit.

Subsequently, the capacitance of the additional capacitors are adjusted based on the detected densities of the plasma for the areas (S620). Here, the additional capacitors are variable capacitors.

Subsequently, the densities of the plasma of areas that are opposite to the plurality of additional coils are controlled (S630). Accordingly, because the density of plasma of an edge area of the substrate may be controlled, the plasma may be uniformly supplied to all areas of the substrate.

As described above, according to various embodiments of the inventive concept, the density of plasma supplied to an edge area of the substrate may be controlled by using an additional antenna, to which a coupling current is applied.

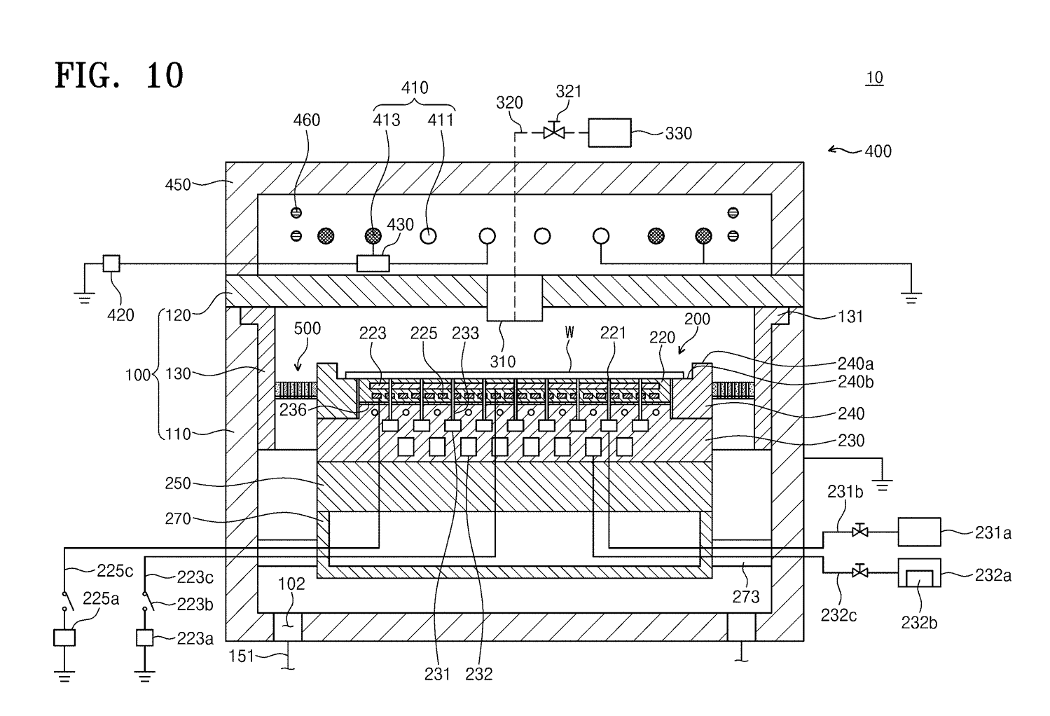

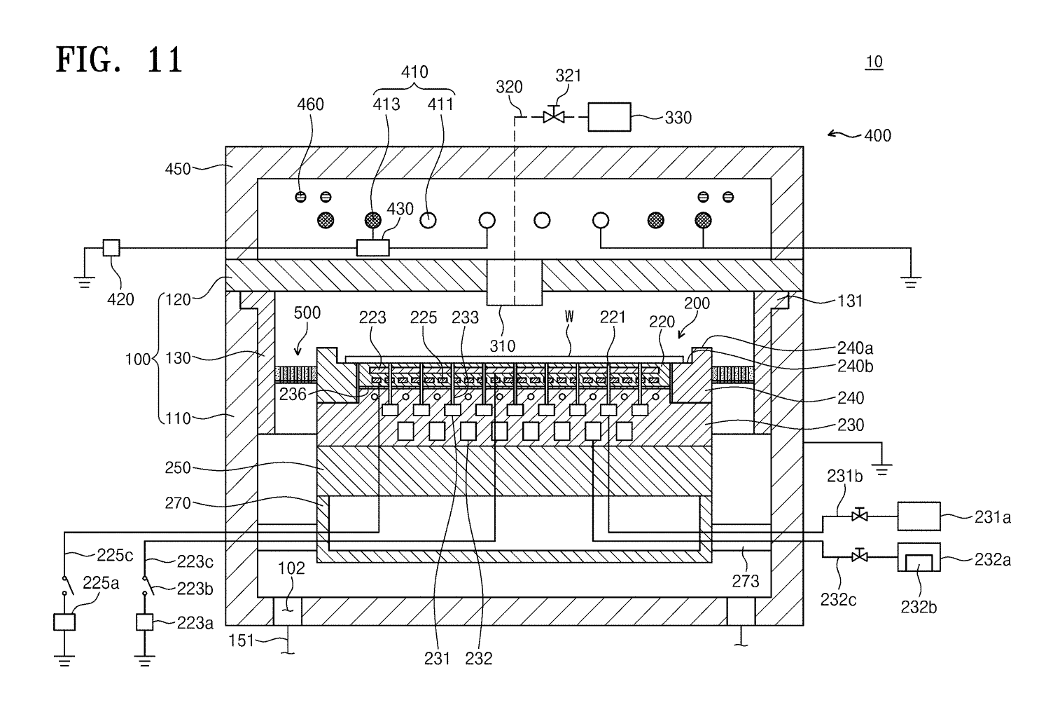

FIGS. 10 and 11 are exemplary views of a substrate treating apparatus according to another embodiment of the inventive concept.

Referring to FIG. 10, the additional antenna 460 may be disposed in a direction that is perpendicular to a disposition direction of the high-frequency antenna 410. In detail, the high-frequency antenna 410 may be disposed in an outward direction from the center of the process chamber 100, and the additional antenna 460 may be disposed in an upward/downward direction of the process chamber 100 outside the high-frequency antenna 410. However, the inventive concept is not limited thereto, and the additional antenna 460 may be disposed in a direction that is parallel to the high-frequency antenna 410, and may be disposed to be inclined at a specific angle. That is, the additional antenna 460 may be disposed in a direction that is perpendicular to the high-frequency antenna 410 or to be inclined at a specific angle to adjust the density of plasma supplied to an edge area of the substrate.

Referring to FIG. 11, the additional antenna 460 may be disposed on a plane that is higher than a plane on which the high-frequency antenna 410 is disposed. That is, the additional antenna 460 may be disposed in a direction that is parallel to the high-frequency antenna 410, and may be disposed at a location that is higher than the high-frequency antenna 410. However, the inventive concept is not limited thereto, and the additional antenna 460 may be disposed at a location that is lower than the high-frequency antenna 410. For example, when a large amount of plasma is to be supplied to the edge area of the substrate, the additional antenna 460 may be disposed at a location that is lower than the high-frequency antenna 410, and when a small amount of plasma is to be supplied to the edge area of the substrate, the additional antenna 460 may be disposed at a location that is higher than the high-frequency antenna 410. Accordingly, according to various embodiments, the density of plasma supplied to the edge area of the substrate may be variously controlled by changing the disposition form or the disposition location of the additional antenna, to which a coupling current is applied.

The above description is a simple exemplification of the technical spirit of the present disclosure, and the present disclosure may be variously corrected and modified by those skilled in the art to which the present disclosure pertains without departing from the essential features of the present disclosure. Therefore, the disclosed embodiments of the inventive concept do not limit the technical spirit of the inventive concept but are illustrative, and the scope of the technical spirit of the inventive concept is not limited by the embodiments of the present disclosure. The scope of the present disclosure should be construed by the claims, and it will be understood that all the technical spirits within the equivalent range fall within the scope of the present disclosure.

What is claimed is:

1. A substrate treating apparatus comprising:
a process chamber having a treatment space in the interior thereof;
a support unit configured to support a substrate in the treatment space;
a gas supply unit configured to supply a treatment gas into the treatment space; and
a plasma generating unit configured to generate plasma from the gas in the treatment space,
wherein the plasma generating unit includes:
a high-frequency power source;
a high-frequency antenna, to which a current is applied from the high-frequency power source; and
an additional antenna provided to be spaced apart from the high-frequency antenna and to which a coupling current is applied from the high-frequency antenna.

2. The substrate treating apparatus of claim 1, wherein the additional antenna is provided independently from the high-frequency power source.

3. The substrate treating apparatus of claim 1, wherein the additional antenna is a closed circuit.

4. The substrate treating apparatus of claim 1, wherein the additional antenna is provided such that an area provided with the additional antenna overlaps an edge area of the interior of the treatment space when viewed from the top.

5. The substrate treating apparatus of claim 1, wherein the additional antenna includes:
a plurality of additional coils, and
wherein the plurality of additional coils are disposed along a lengthwise direction of the high-frequency antenna.

6. The substrate treating apparatus of claim 5, wherein the additional coils are connected to additional capacitors.

7. The substrate treating apparatus of claim 6, wherein some of the additional capacitors connected to the additional coils have different capacitance.

8. The substrate treating apparatus of claim 6, wherein the additional capacitors are variable capacitors.

9. The substrate treating apparatus of claim 5, wherein the plurality of additional coils is provided outside the high-frequency antenna.

10. The substrate treating apparatus of claim 5, wherein the high-frequency antenna includes:
an external antenna,
wherein the external antenna includes:
a plurality of external coils, and
wherein one of the additional coils is coupled to one of the external coils and each of the additional coils is coupled to different external coils.

11. The substrate treating apparatus of claim 10, wherein the high-frequency antenna further includes:
an internal antenna disposed inside the external antenna.

12. The substrate treating apparatus of claim 8, wherein the plasma generating unit further includes:
a controller configured to control the densities of plasma of areas that are opposite to the plurality of additional coils by individually adjusting the capacitance of the additional capacitors.

13. The substrate treating apparatus of claim 12, wherein the support unit further includes:
a sensor configured to detect the densities of plasma for areas of the substrate, and
wherein the controller adjusts the capacitors of the additional capacitors based on the densities of plasma for the areas, which has been detected by the sensor.

14. A plasma generating apparatus comprising:
a high-frequency power source;
a high-frequency antenna, to which a current is applied from the high-frequency power source; and
an additional antenna provided to be spaced apart from the high-frequency antenna and coupled to the high-frequency antenna such that a coupling current is applied from the high-frequency antenna to the additional antenna.

15. The plasma generating apparatus of claim 14, wherein the high-frequency antenna further includes:
an external antenna,
wherein the external antenna includes:
an external coil, one end of which is connected to the high-frequency antenna and an opposite end of which is grounded,
wherein the additional antenna includes:
a plurality of additional coils that are provided independently from the high-frequency power source, and
wherein the additional coils are coupled to the external coil.

16. The plasma generating apparatus of claim 15, wherein the additional coils are connected to additional capacitors.

17. The plasma generating apparatus of claim 16, wherein some of the additional capacitors connected to the additional coils have different capacitance.

18. The plasma generating apparatus of claim 16, wherein the additional capacitors are variable capacitors.

19. The plasma generating apparatus of claim 18, further comprising:
a controller configured to control the densities of plasma of areas that are opposite to the plurality of additional coils by individually adjusting the capacitance of the additional capacitors.

20. A substrate treating method of a substrate treating apparatus, the substrate treating apparatus including: a process chamber having a treatment space in the interior thereof; a high-frequency antenna configured to generate plasma in the treatment space; and an additional antenna, to which a coupling current is applied from the high-frequency antenna, the method comprising:
controlling the density of plasma of an edge area of the interior of the treatment space by controlling the additional antenna.

21. The substrate treating method of claim 20, wherein the additional antenna includes:
a plurality additional coils; and
additional capacitors connected to the additional coils.

22. The substrate treating method of claim 21, wherein each of the additional capacitors has different capacitance.

23. The substrate treating method of claim 21, wherein the additional capacitors are variable capacitors, and
wherein the controlling of the plasma includes:
controlling the densities of the plasma of areas that are opposite to the plurality of additional coils by individually adjusting the capacitance of the additional capacitors.

24. The substrate treating method of claim 23, further comprising:
detecting the densities of plasma for areas of the substrate,
wherein the controlling of the plasma includes:
adjusting the capacitance of the additional capacitors based on the densities of plasma for areas of the substrate.
